(19) United States
(12) Patent Application Publication
(10) Pub. No.: US 2025/0254983 A1
(43) Pub. Date: Aug. 7, 2025

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventor: Koh YOSHIKAWA, Matsumoto-city (JP)

(21) Appl. No.: 19/185,148

(22) Filed: Apr. 21, 2025

Related U.S. Application Data
(63) Continuation of application No. PCT/JP2024/014534, filed on Apr. 10, 2024.

(30) Foreign Application Priority Data
May 23, 2023 (JP) 2023-084932

(51) Int. Cl. H10D 84/80; H10D 8/00; H10D 12/00; H10D 12/01; H10D 62/10; H10D 62/60; H10D 64/23

(52) U.S. Cl. CPC H10D 84/811; H10D 8/422; H10D 12/481; H10D 62/103; H10D 62/60; H10D 64/232; H10D 12/038

(57) ABSTRACT

A semiconductor device including a transistor portion and a diode portion is provided, the semiconductor device including: a plurality of trench portions provided at a front surface of a semiconductor substrate; a drift region of a first conductivity type; a base region of a second conductivity type; an emitter region of the first conductivity type having a higher doping concentration than the drift region; a first contact region of the second conductivity type having a higher doping concentration than the base region; an anode region of the second conductivity type; and a second contact region of the second conductivity type having a higher doping concentration than the anode region, wherein an amount per unit volume of dopants of the second conductivity type in the mesa portion of the diode portion is greater than or equal to that in the mesa portion of the transistor portion.

The contents of the following patent application(s) are incorporated herein by reference:
NO. 2023-084932 filed in JP on May 23, 2023
NO. PCT/JP2024/014534 filed in WO on Apr. 10, 2024.

### BACKGROUND

### 1. Technical Field

The present invention relates to a semiconductor device and a method for manufacturing a semiconductor device.

### 2. Related Art

Patent Document 1 discloses a semiconductor device in which “holes injected from the collector layer 11 can be easily extracted from the contact layer 5”.

### PRIOR ART DOCUMENTS

### Patent Document

Patent Document 1: Japanese Patent Application Publication No. 2022-67972

### BRIEF DESCRIPTION OF THE DRAWINGS

FIG. 1A is a view showing an example of an upper surface of a semiconductor device 100.

FIG. 1B is a view showing an example of a cross section a-a′ of the semiconductor device 100.

FIG. 1C is a view showing an example of a cross section b-b′ of the semiconductor device 100.

FIG. 1D is a view showing an example of a cross section c-c′ of the semiconductor device 100.

FIG. 2 is a view showing a modified example of the upper surface of the semiconductor device 100.

FIG. 3A is a view showing a modified example of the upper surface of the semiconductor device 100.

FIG. 3B is a view showing an example of a cross section d-d′ of the semiconductor device 100.

FIG. 4 is a view showing a modified example of the upper surface of the semiconductor device 100.

FIG. 5A is a diagram showing a relationship between a doping concentration of a cathode region 82 and a forward voltage Vf of a diode portion 80.

FIG. 5B is a diagram showing a relationship between the forward voltage Vf and a reverse recovery loss Err of the diode portion 80.

FIG. 6 is a flowchart showing an example of a method for manufacturing the semiconductor device 100.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

In the present specification, one side in a direction parallel to a depth direction of a semiconductor substrate is referred to as an “upper” side, and another side is referred to as a “lower” side. One surface of two principal surfaces of a substrate, a layer, or another member is referred to as an upper surface, and another surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described using orthogonal coordinate axes of an x axis, a y axis, and a z axis. The orthogonal coordinate axes merely specify relative positions of components, and do not limit a specific direction. For example, the z axis is not limited to indicating a height direction with respect to the ground. It should be noted that a +z axis direction and a −z axis direction are directions opposite to each other. If a z axis direction is described without describing the signs, it means that the direction is parallel to the +z axis and the −z axis.

In the present specification, a surface parallel to the upper surface of the semiconductor substrate is referred to as an XY surface, and an orthogonal axis parallel to the upper surface and the lower surface of the semiconductor substrate is referred to as the x axis and the y axis. In addition, an axis perpendicular to the upper surface and the lower surface of the semiconductor substrate is referred to as the z axis. The depth direction of a semiconductor substrate may be referred to as the z axis. It should be noted that as used in the present specification, the view of the semiconductor substrate in the z axis direction is referred to as a planar view. In addition, in the present specification, a direction parallel to the upper surface and the lower surface of the semiconductor substrate may be referred to as a horizontal direction, including the x axis direction and the y axis direction.

Each embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example respectively have opposite polarities.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as the P type or the N type. In the present specification, the impurities may particularly mean either donors of the n type or acceptors of the p type, and may be described as dopants. In the present specification, doping means introducing the donor or the acceptor into the semiconductor substrate and turning it into a semiconductor presenting a conductivity type of the n type or a semiconductor presenting a conductivity type of the p type.

In the present specification, a doping concentration means a concentration of the donor or a concentration of the acceptor in a thermal equilibrium state.

In the present specification, a description of a P+ type or an N+ type means a doping concentration higher than that of the P type or the N type, and a description of a P− type or an N− type means a doping concentration lower than that of the P type or the N type. In addition, in the present specification, a description of a P++ type or an N++ type means a doping concentration higher than that of the P+ type or the N+ type.

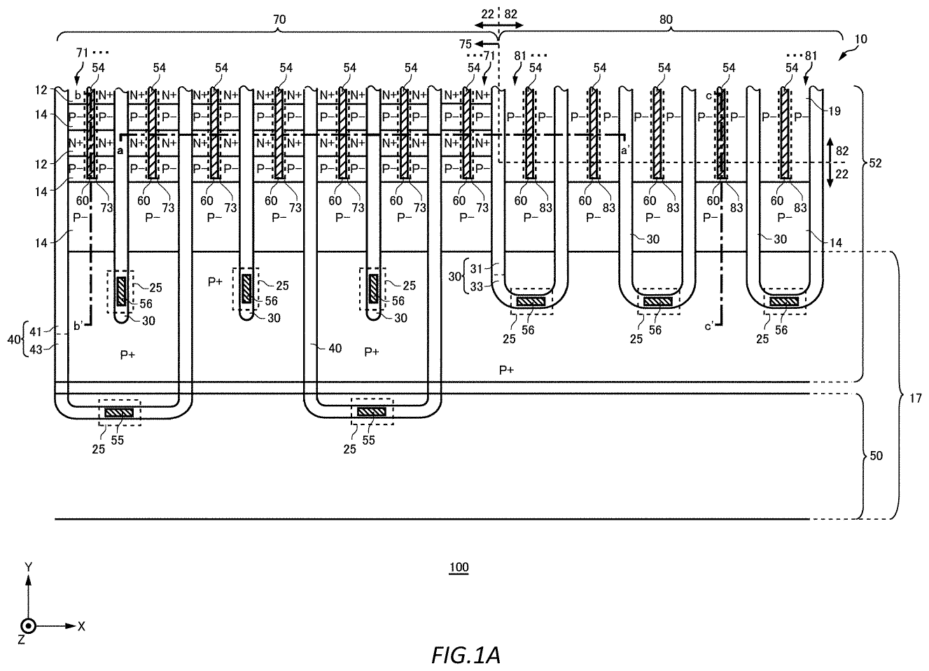

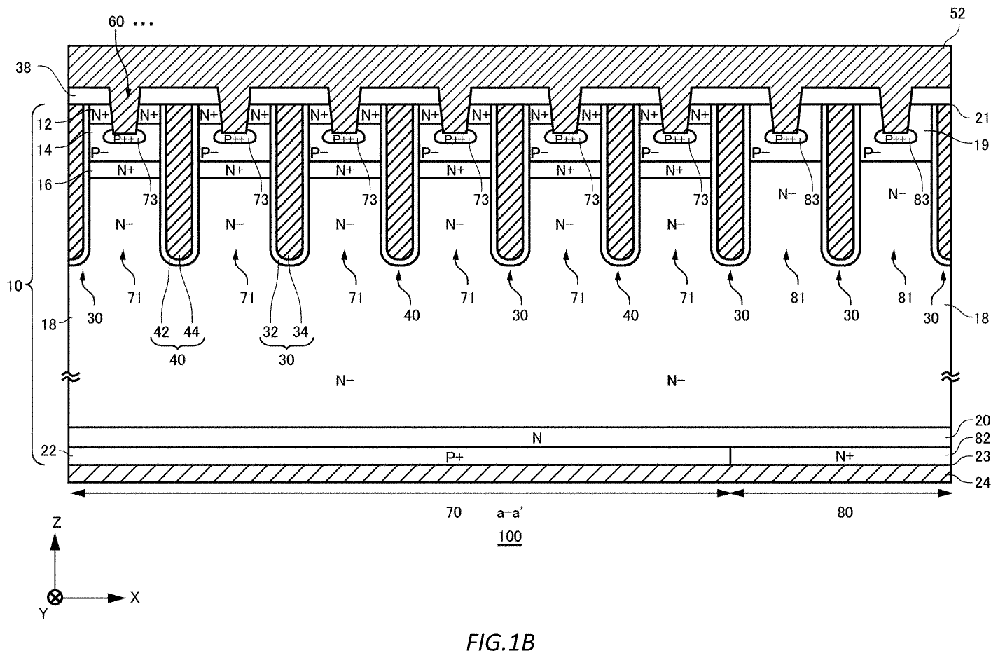

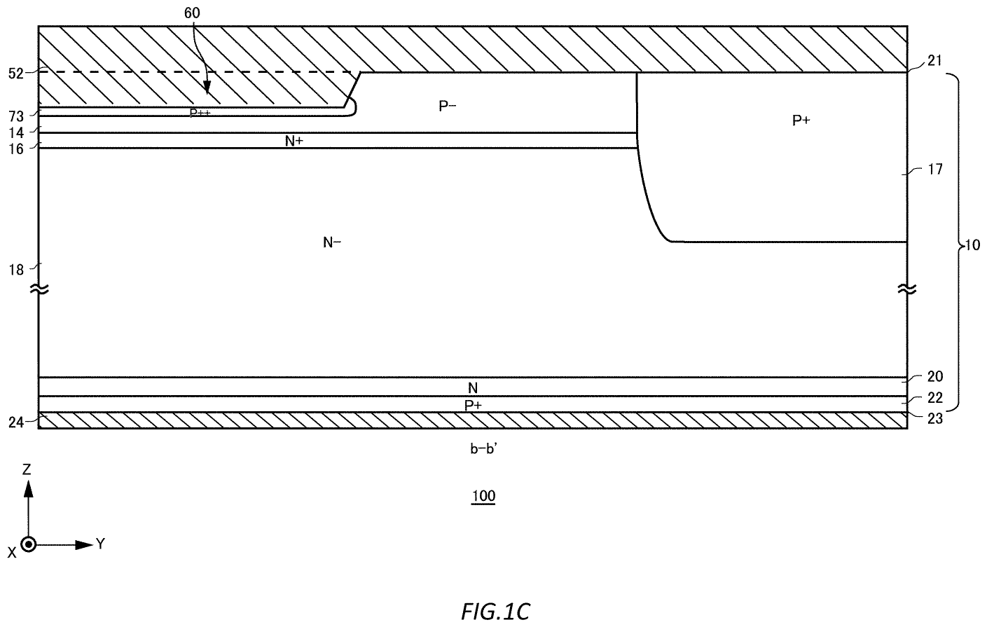

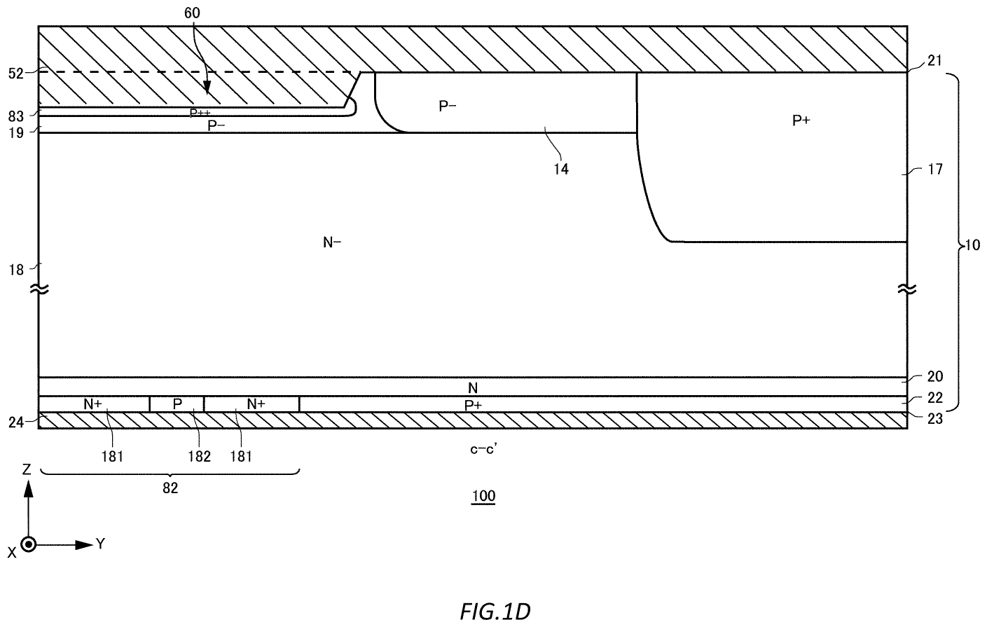

FIG. 1A shows an example of an upper surface of a semiconductor device 100. The semiconductor device 100 in the present example is a semiconductor chip including a transistor portion 70 and a diode portion 80. For example, the semiconductor device 100 is a reverse conducting IGBT (RC-IGBT). The transistor portion 70 may include a boundary region in a portion adjacent to the diode portion 80. The transistor portion 70 in the present example does not include the boundary region.

A front surface 21 of a semiconductor substrate 10 is provided with a plurality of trench portions which extend in a predetermined direction (a Y axis direction in the present example), and are arrayed in a predetermined direction (an X axis direction in the present example). The front surface 21 will be described below. The plurality of trench portions have a gate trench portion 40 to which a gate potential is applied, and a dummy trench portion 30 to which a potential different from the gate potential is applied.

The transistor portion 70 is a region where a collector region 22 provided on a back surface side of the semiconductor substrate 10 is projected onto an upper surface of the semiconductor substrate 10. The collector region 22 has the second conductivity type. The collector region 22 in the present example is of the P+ type as an example. The transistor portion 70 includes a transistor such as an IGBT. The transistor portion 70 in the present example includes a main region 75.

The main region 75 is a region in which a channel region is formed during an operation of the semiconductor device 100 and which is operated as a transistor. The main region 75 may be a region of the transistor portion 70 other than the boundary region. The transistor portion 70 in the present example does not have the boundary region, and thus the transistor portion 70 and the main region 75 coincide with each other. That is, the main region 75 of the transistor portion 70 is provided to be adjacent to the diode portion 80.

The diode portion 80 is a region where a cathode region 82 provided at a back surface of the semiconductor substrate 10 is projected onto the upper surface of the semiconductor substrate 10. The cathode region 82 has the first conductivity type. The cathode region 82 in the present example is of the N+ type as an example. The diode portion 80 includes a diode such as a free wheel diode (FWD) provided to be adjacent to the transistor portion 70 at the upper surface of the semiconductor substrate 10.

In the transistor portion 70, an anode region 19 may be formed at a front surface; and in the diode portion 80, an emitter region 12 and a base region 14 may be formed at a front surface. In a trench array direction (in the present example, the X axis direction) of the plurality of trench portions, a distance from a boundary between a region in which the emitter region 12 or the base region 14 is provided, and a region in which the anode region 19 is provided, to a boundary between the collector region 22 and the cathode region 82, may be 0 μm or more, and may be 10 μm or less. In the present example, the distance is 0 μm.

FIG. 1A shows a surrounding region of a chip end portion, which is an edge side of the semiconductor device 100, and another region is omitted. For example, an edge termination structure portion may be provided in a region on a negative side in the y axis direction in the semiconductor device 100 in the present example. The edge termination structure portion reduces electric field strength on an upper surface side of the semiconductor substrate 10. The edge termination structure portion has, for example, a guard ring, a field plate, a RESURF, and a structure combining these. It should be noted that although the present example describes an edge on the negative side in the y axis direction for convenience, the same applies to another edge of the semiconductor device 100. The edge termination structure portion may be provided to surround an active region including the transistor portion 70 and the diode portion 80.

The semiconductor substrate 10 may be a silicon substrate, may be a silicon carbide substrate, or may be a nitride semiconductor substrate or the like of gallium nitride or the like. The semiconductor substrate 10 in the present example is the silicon substrate.

The semiconductor device 100 in the present example includes the gate trench portion 40, the dummy trench portion 30, the emitter region 12, the base region 14, a well region 17, and the anode region 19, at the front surface 21 of the semiconductor substrate 10. The semiconductor device 100 of the present example includes a first contact region 73 provided in a mesa portion 71 of the transistor portion 70, and a second contact region 83 provided in a mesa portion 81 of the diode portion 80. In addition, the semiconductor device 100 in the present example includes an emitter electrode 52 and a gate metal layer 50 which are provided above the front surface 21 of the semiconductor substrate 10.

The emitter electrode 52 is provided above the gate trench portion 40, the dummy trench portion 30, the emitter region 12, the base region 14, the well region 17, and the anode region 19. In addition, the gate metal layer 50 is provided above the gate trench portion 40 and the well region 17.

The emitter electrode 52 and the gate metal layer 50 are formed of a material containing metal. At least a part of a region of the emitter electrode 52 may be formed of metal such as aluminum (Al), or an alloy containing aluminum, for example, a metal alloy such as an aluminum-silicon alloy (AlSi) and an aluminum-silicon-copper alloy (AlSiCu). At least a part of a region of the gate metal layer 50 may be formed of metal such as aluminum (Al), or an alloy containing aluminum, for example, a metal alloy such as an aluminum-silicon alloy (AlSi) and an aluminum-silicon-copper alloy (AlSiCu). The emitter electrode 52 and the gate metal layer 50 may have barrier metal formed of titanium, a titanium compound, or the like in a lower layer of a region formed of aluminum or an alloy containing aluminum, or the like. The emitter electrode 52 and the gate metal layer 50 are provided separately from each other.

The emitter electrode 52 and the gate metal layer 50 are provided with an interlayer dielectric film 38 being sandwiched therebetween, above the semiconductor substrate 10. The interlayer dielectric film 38 is omitted in FIG. 1A. A contact hole 54, a contact hole 55, and a contact hole 56 are provided to pass through the interlayer dielectric film 38.

The contact hole 54 is provided to extend from an upper surface of the interlayer dielectric film 38 in the depth direction of the semiconductor substrate 10. The contact hole 54 has a bottom portion and a side portion. The contact hole 54 electrically connects the emitter electrode 52 to the semiconductor substrate 10. The contact hole 54 is provided to extend in a trench extension direction. The contact hole 54 in the present example is arranged in a stripe shape along the gate trench portion 40 and the dummy trench portion 30.

The contact holes 54 are provided in both of the transistor portion 70 and the diode portion 80. The contact hole 54 is formed at an upper surface of each region of the emitter region 12 and the base region 14 in the transistor portion 70. The contact hole 54 is provided above the anode region 19 in the diode portion 80. The contact hole 54 is not provided above the well regions 17 provided at both ends in the Y axis direction. In this way, one or more contact holes 54 are formed in the interlayer dielectric film. The one or more contact holes 54 may be provided to extend in the extension direction. A trench contact portion 60 may be provided in the contact hole 54. That is, the trench contact portion 60 may be provided in both of the transistor portion 70 and the diode portion 80. The trench contact portion 60 will be described below.

The contact hole 55 connects the gate metal layer 50 with a gate conductive portion inside the transistor portion 70. In the contact hole 55, a plug formed of tungsten or the like may be formed via the barrier metal.

The contact hole 56 connects the emitter electrode 52 with a dummy conductive portion inside the dummy trench portion 30. In the contact hole 56, a plug formed of tungsten or the like may be formed via the barrier metal.

A connection portion 25 electrically connects a front surface side electrode such as the emitter electrode 52 or the gate metal layer 50, to the semiconductor substrate 10. In an example, the connection portion 25 is provided between the gate metal layer 50 and the gate conductive portion. The connection portion 25 is also provided between the emitter electrode 52 and the dummy conductive portion. The connection portion 25 is formed of a conductive material such as polysilicon doped with an impurity. The connection portion 25 in the present example is formed of polysilicon (N+) doped with an impurity of the N type. The connection portion 25 is provided above the front surface 21 of the semiconductor substrate 10 via a dielectric film such as an oxide film, or the like.

The gate trench portion 40 is put into an array at a predetermined interval along a predetermined array direction (the X axis direction in the present example). The gate trench portion 40 in the present example may have two extension parts 41 which extend along an extension direction (the Y axis direction in the present example) parallel to the front surface 21 of the semiconductor substrate 10 and perpendicular to the array direction, and a connection part 43 which connects the two extension parts 41.

At least a part of the connection part 43 may be formed to have a curved shape. Connecting end portions of the two extension parts 41 of the gate trench portion 40 can reduce electric field strength at the end portions of the extension parts 41. The gate metal layer 50 may be connected to the gate conductive portion at the connection part 43 of the gate trench portion 40.

The dummy trench portion 30 is a trench portion electrically connected to the emitter electrode 52. Similar to the gate trench portions 40, the dummy trench portions 30 are arrayed at predetermined intervals along a predetermined array direction (the X axis direction in the present example). Similar to the gate trench portion 40, the dummy trench portion 30 in the present example may have a U shape at the front surface 21 of the semiconductor substrate 10. That is, the dummy trench portion 30 may have two extension parts 31 which extend along the extension direction, and a connection part 33 which connects the two extension parts 31.

The main region 75 of the transistor portion 70 in the present example has a structure in which one gate trench portion 40 and one dummy trench portion 30 are repeatedly arrayed. That is, the transistor portion 70 in the present example has the gate trench portions 40 and the dummy trench portions 30 at a ratio of 1:1. For example, the transistor portion 70 includes one extension part 31 between two extension parts 41. In addition, the transistor portion 70 has one extension part 41 between two extension parts 31.

It is to be noted that the ratio between the gate trench portions 40 and the dummy trench portions 30 is not limited to that in the present example. The ratio between the gate trench portions 40 and the dummy trench portions 30 may be 2:3, or may be 2:4. In addition, the transistor portion 70 may not have the dummy trench portions 30 with all trench portions being the gate trench portions 40.

The mesa portion 71 is a mesa portion provided to be adjacent to the trench portion in a plane parallel to the front surface 21 of the semiconductor substrate 10. The mesa portion may be a part of the semiconductor substrate 10 sandwiched between two adjacent trench portions, and may be a part from the front surface 21 of the semiconductor substrate 10 to a depth of a lowermost bottom portion of each trench portion. An extension part of each trench portion may be defined as one trench portion. That is, the region sandwiched between two extension parts may be defined as a mesa portion.

The mesa portion 71 is provided to be adjacent to at least one of the dummy trench portion 30 or the gate trench portion 40 in the transistor portion 70. The mesa portion 71 has the well region 17, the emitter region 12, and the base region 14, at the front surface 21 of the semiconductor substrate 10. In the mesa portion 71, the emitter region 12 and the base region 14 are alternately provided in the extension direction of the trench portion (the Y axis direction in the present example), at the front surface 21 of the semiconductor substrate 10.

The base region 14 is a region of the second conductivity type provided above a drift region 18 described below. The base region 14 is of the P-type as an example. The base regions 14 may be provided at both end portions of the mesa portion 71 in the Y axis direction at the front surface 21 of the semiconductor substrate 10. In FIG. 1A, only one end portion of the base region 14 in the Y axis direction is shown.

The emitter region 12 is a region of the first conductivity type which is provided above the base region 14 and has a doping concentration higher than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one to another of two trench portions with the mesa portion 71 being sandwiched therebetween.

In addition, the emitter region 12 may be, or may not be in contact with the dummy trench portion 30. The emitter region 12 in the present example is in contact with the dummy trench portion 30.

The mesa portion 81 is provided in a region sandwiched between the dummy trench portions 30 adjacent to each other in the diode portion 80. The mesa portion 81 has the anode region 19 at the front surface 21 of the semiconductor substrate 10. The mesa portion 81 in the present example has the anode region 19, the base region 14, and the well region 17 on the negative side of the Y axis direction.

The anode region 19 is a region of the second conductivity type which is provided above the drift region 18. A doping concentration of the anode region 19 may be the same as a doping concentration of the base region 14, and may be higher than a doping concentration of the base region 14. The doping concentration of the anode region 19 in the present example is the same as the doping concentration of the base region 14. The anode region 19 in the present example is of P-type, as an example.

The anode region 19 in the present example is provided at the front surface 21 of the mesa portion 81. The anode region 19 may be provided in the X axis direction from one to another of two dummy trench portions 30 with the mesa portion 81 being sandwiched therebetween. The anode region 19 may be, or may not be in contact with the dummy trench portion 30. The anode region 19 in the present example is in contact with the dummy trench portion 30.

The doping concentration of the anode region 19 in the present example may be 1E16 cm⁻³ or more, and may be 1E18 cm⁻³ or less. It should be noted that the character E means a power of 10, and for example, 1E18 cm⁻³ means 1×10¹⁸ cm⁻³. The anode region 19 may have a peak of the doping concentration in the depth direction of the semiconductor substrate 10. In addition, in the depth direction of the semiconductor substrate 10, a lower end of the anode region 19 may have the same depth as a lower end of the base region 14, or may be at a deeper position than that of the lower end of the base region 14.

The first contact region 73 is a region of the second conductivity type which has a doping concentration higher than that of the base region 14. The first contact region 73 in the present example is, as an example, of the P++ type. The doping concentration of the first contact region 73 in the transistor portion 70 may be 1E19 cm⁻³ or more, and may be 1E21 cm⁻³ or less.

In the transistor portion 70, the first contact region 73 may be provided to extend in the extension direction of the plurality of trench portions. In the present example, the first contact region 73 is provided to extend along the emitter regions 12 and the base regions 14 which are alternately provided at the front surface 21 of the semiconductor substrate 10.

The second contact region 83 is a region of the second conductivity type which has a doping concentration higher than that of the anode region 19. In the present example, the second contact region 83 is, as an example, of the P++ type. The doping concentration of the second contact region 83 may be the same as, or may be different from the doping concentration of the first contact region. The doping concentration of the second contact region 83 may be higher than the doping concentration of the first contact region 73. The doping concentration of the second contact region 83 in the diode portion 80 may be 1E19 cm⁻³ or more, and may be 1E21 cm⁻³ or less.

In the diode portion 80, the second contact region 83 may be provided to extend in the extension direction of the plurality of trench portions. In the present example, the second contact region 83 is provided to correspond to the extension direction of the first contact region 73.

FIG. 1B shows an example of a cross section a-a′ in FIG. 1A. The cross section a-a′ is an XZ plane which passes through the emitter region 12 in the transistor portion 70. The semiconductor device 100 in the present example has, in the cross section a-a′: the semiconductor substrate 10 provided with the emitter region 12, the base region 14, an accumulation region 16, the drift region 18, a buffer region 20, the first contact region 73, and the second contact region 83; the interlayer dielectric film 38; the trench contact portion 60; the emitter electrode 52; and a collector electrode 24. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N-type as an example. The drift region 18 may be a region which has remained without another doping region being formed in the semiconductor substrate 10. That is, the doping concentration of the drift region 18 may be a doping concentration of the semiconductor substrate 10.

The buffer region 20 of the first conductivity type may be provided below the drift region 18. The buffer region 20 in the present example is of the N type. A doping concentration of the buffer region 20 is higher than the doping concentration of the drift region 18. The buffer region 20 may be a field stopper layer configured to prevent a depletion layer, which expands from a lower surface side of the base region 14, from reaching the collector region 22 and the cathode region 82.

The collector electrode 24 is formed at a back surface 23 of the semiconductor substrate 10. The collector electrode 24 is formed of a conductive material such as metal.

The base region 14 is a region of the second conductivity type which is provided above the drift region 18. The doping concentration of the base region 14 may be the same as, or may be different from the doping concentration of the anode region 19. The doping concentration of the base region 14 may be 1E16 cm⁻³ or more, and 1E18 cm⁻³ or less. The base region 14 may be provided below the emitter region 12. The base region 14 is provided in contact with the gate trench portion 40. The base region 14 may be provided in contact with the dummy trench portion 30.

The accumulation region 16 is a region of the first conductivity type which is provided below the base region 14 in the depth direction of the semiconductor substrate 10, and which has a doping concentration higher than that of the drift region 18. The accumulation region 16 in the present example is of the N+ type as an example. The accumulation region 16 is provided in the main region 75 of the transistor portion 70, and is not provided in the diode portion 80. By providing the first accumulation region 16, a carrier injection enhancement effect (IE effect) can be increased, and an on voltage of the transistor portion 70 can be reduced.

One or more gate trench portions 40 and one or more dummy trench portions 30 are provided at the front surface 21. Each trench portion is provided from the front surface 21 to the drift region 18. In a region provided with at least any of the emitter region 12, the base region 14, the accumulation region 16, or the anode region 19, each trench portion also passes through these regions to reach the drift region 18. A configuration in which a trench portion passes through a doping region is not limited to a configuration which is made by forming a doping region and then forming a trench portion in this order. The configuration of the trench portion passing through the doping region includes a configuration of the doping region being formed between the trench portions after forming the trench portion.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor at the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region facing the base region 14 adjacent on a mesa portion 71 side with the gate dielectric film 42 being sandwiched therebetween, in the depth direction of the semiconductor substrate 10. When a predetermined voltage is applied to the gate conductive portion 44, a channel is formed by an electron inversion layer in a surface layer of the base region 14 at a boundary in contact with the gate trench.

The dummy trench portion 30 may have the same structure as that of the gate trench portion 40. The dummy trench portion 30 has a dummy trench, a dummy dielectric film 32, and a dummy conductive portion 34 which are formed on a front surface 21 side. The dummy dielectric film 32 is formed to cover an inner wall of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 is covered with the interlayer dielectric film 38 on the front surface 21.

The interlayer dielectric film 38 is provided on the front surface 21. The emitter electrode 52 is provided above the interlayer dielectric film 38. The interlayer dielectric film 38 is provided with one or more trench contact portions 60 to electrically connect the emitter electrode 52 to the semiconductor substrate 10. Similar to the trench contact portion 60, the contact hole 55 and the contact hole 56 may also be provided to pass through the interlayer dielectric film 38.

The trench contact portion 60 passes through the interlayer dielectric film 38 and the emitter region 12, to reach the base region 14 or the anode region 19. The trench contact portion 60 electrically connects the emitter electrode 52 to the semiconductor substrate 10. In the present example, a depth of a lower end of the trench contact portion 60 is deeper than a depth of a lower end of the emitter region 12, in the depth direction of the semiconductor substrate 10. This makes it possible to enhance a latch-up withstand capability of the semiconductor device 100.

The first contact region 73 is provided at the lower end of the trench contact portion 60. The first contact region 73 may be provided to partially cover a bottom portion and a side wall of the trench contact portion 60. In the transistor portion 70, the first contact region 73 is provided to be spaced apart from the emitter region 12. In the transistor portion 70, the first contact region 73 is provided to be spaced apart from the gate trench portion 40.

In an example, the first contact region 73 is formed by implanting a dopant via the trench contact portion 60. The first contact region 73 may be formed first, and then the trench contact portion 60 may be provided. Providing the first contact region 73 makes it possible to lower a resistance of the bottom portion of the trench contact portion 60 in the transistor portion 70, and to suppress a latch-up destruction.

The second contact region 83 is provided at the lower end of the trench contact portion 60. The second contact region 83 may be provided to partially cover the bottom portion and the side wall of the trench contact portion 60. In an example, the second contact region 83 is formed by implanting a dopant via the trench contact portion 60. The second contact region 83 may be formed first, and then the trench contact portion 60 may be provided.

The doping concentration of the second contact region 83 may be the same as, or may be different from the doping concentration of the first contact region 73. In the present example, the doping concentration of the second contact region 83 is higher than the doping concentration of the first contact region 73.

An amount per unit volume of dopants of the second conductivity type in the mesa portion 81 of the diode portion 80 may be the same as, or may be different from an amount per unit volume of dopants of the second conductivity type in the mesa portion 71 of the transistor portion 70. In the present specification, the amount per unit volume of dopants of the second conductivity type in the mesa portion 71 of the transistor portion 70, may be an amount obtained by dividing
a total amount of dopants that are contained in the base region 14 and the first contact region 73, by a volume of the mesa portion 71. In the present specification, the amount per unit volume of dopants of the second conductivity type in the mesa portion 81 of the diode portion 80, may be an amount obtained by dividing
a total amount of dopants that are contained in the anode region 19 and the second contact region 83, by a volume of the mesa portion 81. In the present example, the amount per unit volume of dopants of the second conductivity type in the mesa portion 81 of the diode portion 80 is greater than or equal to the amount per unit volume of dopants of the second conductivity type in the mesa portion 71 of the transistor portion 70. In this manner, a hole injection from the transistor portion 70 to the diode portion 80 is suppressed, which makes it possible to reduce a reverse recovery loss Err.

The amount per unit volume of dopants of the second conductivity type in the mesa portion 81 of the diode portion 80 may be the same as, or may be different from the amount per unit volume of dopants of the second conductivity type in the mesa portion 71 of the main region 75. In the present example, the amount per unit volume of dopants of the second conductivity type in the mesa portion 81 of the diode portion 80 is greater than or equal to the amount per unit volume of dopants of the second conductivity type in the mesa portion 71 of the main region 75.

The collector region 22 is provided, in the transistor portion 70, at the back surface 23 of the semiconductor substrate 10. The collector region 22 is a region of the second conductivity type which has a doping concentration higher than that of the base region 14.

In the diode portion 80, the cathode region 82 is provided at the back surface 23 of the semiconductor substrate 10. The cathode region 82 is a region of the first conductivity type which has a doping concentration higher than that of the drift region 18. The doping concentration of the cathode region in the present example may be 1E18 cm⁻³ or more, and may be 1E21 cm⁻³ or less.

The doping concentration of the cathode region 82 may be changed according to the amount per unit volume of dopants of the second conductivity type in the mesa portion 71 of the transistor portion 70, and the amount per unit volume of dopants of the second conductivity type in the mesa portion 81 of the diode portion 80. This makes it possible to improve the trade-off between a forward voltage Vf and the reverse recovery loss Err in the diode portion 80. The details will be described below.

The semiconductor device 100 in the present example does not have a lifetime control region, inside the semiconductor substrate 10. This eliminates a need for an additional ion implantation or the like to form the lifetime control region, which makes it possible to reduce a cost.

FIG. 1C shows an example of a cross section b-b′ in FIG. 1A. The cross section b-b′ is a YZ plane along the trench contact portion 60 in the transistor portion 70.

The first contact region 73 is provided to extend in the extension direction of the trench contact portion 60. The first contact region 73 may partially cover the bottom portion and the side wall of the trench contact portion 60. The first contact region 73 may cover the side wall of the trench contact portion 60 at an end portion in the trench extension direction (in the present example, the Y axis direction).

The well region 17 is a region of the second conductivity type provided to be closer to the front surface 21 side of the semiconductor substrate 10 than the drift region 18. The well region 17 is an example of a well region provided on an edge side of the semiconductor device 100. The well region 17 is of the P+ type as an example.

The well region 17 is formed in a predetermined range from an end portion of the active region on a side where the gate metal layer 50 is provided. A diffusion depth of the well region 17 may be deeper than depths of the gate trench portion 40 and the dummy trench portion 30. Partial regions of the gate trench portion 40 and the dummy trench portion 30 on a gate metal layer 50 side are formed in the well region 17. Bottoms of ends in the extension direction of the gate trench portion 40 and the dummy trench portion 30 may be covered with the well region 17.

FIG. 1D shows an example of a cross section c-c′ in FIG. 1A. The cross section c-c′ is a YZ plane along the trench contact portion 60 in the diode portion 80.

The second contact region 83 is provided to extend in the extension direction of the trench contact portion 60. The second contact region 83 may partially cover the bottom portion and the side wall of the trench contact portion 60. The second contact regions 83 may be provided discretely in the extension direction of the trench contact portion 60. The second contact region 83 may cover the side wall of the trench contact portion 60 at an end portion in the trench extension direction (in the present example, the Y axis direction).

A first cathode portion 181 is a region of the first conductivity type which has a higher doping concentration than that of the drift region 18. In an example, the first cathode portion 181 is of the N+ type. A width of the first cathode portion 181 in the trench extension direction (the Y axis direction) may be greater than a width of a second cathode portion 182 in the trench extension direction.

The second cathode portion 182 is a region of the second conductivity type which is provided to be adjacent to the first cathode portion 181 at the back surface 23 of the semiconductor substrate 10. That is, the second cathode portion 182 may be in direct contact with the first cathode portion 181. In an example, the second cathode portion 182 is of the P type.

The first cathode portion 181 may be formed by an ion implantation of the dopant of the N type, after an ion implantation of the dopant of the P type by an ion implantation step of forming the second cathode portion 182. Conversely, the second cathode portion 182 may be formed by an ion implantation of the dopant of the P type, after an ion implantation of the dopant of the N type by an ion implantation step of forming the first cathode portion 181.

The first cathode portion 181 and the second cathode portion 182 are arranged to form a boundary of a contact with each other. The first cathode portion 181 and the second cathode portion 182 may be alternately arranged in any direction. The first cathode portions 181 and the second cathode portion 182 in the present example are alternately arrayed in the trench extension direction (for example, the Y axis direction), but may be alternately arrayed in the trench array direction (for example, the X axis direction). The first cathode portion 181 and the second cathode portion 182 may be arranged in the stripe shapes in a top plan view. One of the first cathode portion 181 and the second cathode portion 182 may be formed in a dot shape.

In the cathode region 82 in the diode portion 80 in the present example, the second cathode portion 182 may be provided. In the cathode region 82 in the diode portion 80 in the present example, the first cathode portion 181 and the second cathode portion 182 may be alternately provided. In the cathode region 82 in the diode portion 80 in the present example, the first cathode portion 181 and the second cathode portion 182 may be provided to contact each other. In this manner, the concentration of the dopant of the first conductivity type in the cathode region 82 is decreased, and the forward voltage Vf of the diode portion 80 can be enhanced.

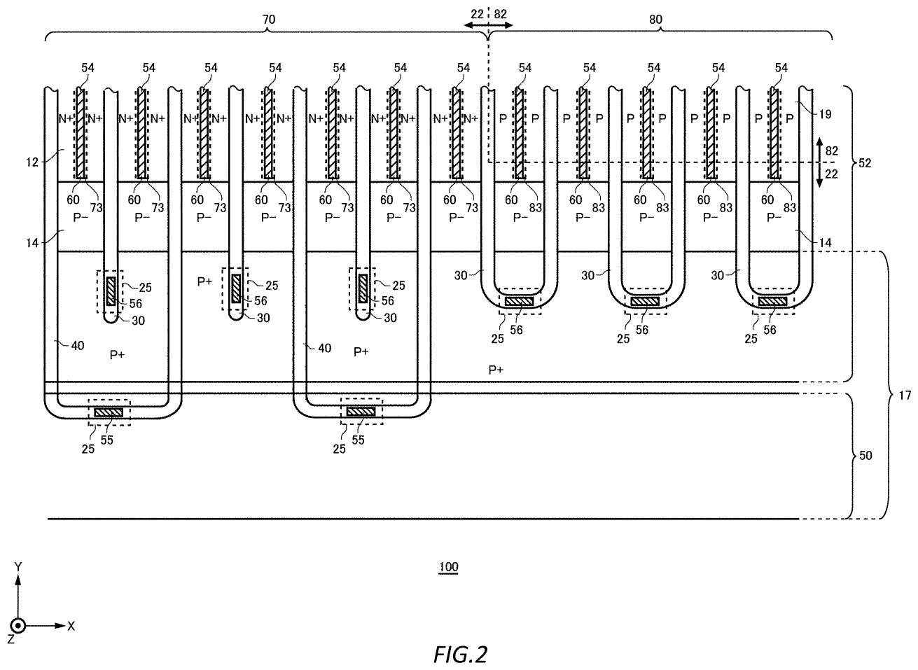

FIG. 2 is a view showing a modified example of the upper surface of the semiconductor device 100. With reference to FIG. 2, a difference from FIG. 1A will be described.

In the modified example shown in FIG. 2, at the front surface 21 of the semiconductor substrate 10, the emitter region 12 is provided to extend in the extension direction of the plurality of trench portions. The emitter region 12 may be provided to extend from one base region 14, which is adjacent to the well region 17 in the Y axis direction, to another base region 14. This reduces the amount per unit volume of dopants of the second conductivity type in the transistor portion 70, and reduces an amount of hole injections from the transistor portion 70 to the diode portion 80, and it is possible to reduce the forward voltage Vf of the diode portion 80.

In the modified example shown in FIG. 2, the doping concentration of the anode region 19 is higher than the doping concentration of the base region 14. In the modified example, the anode region 19 is of the P type. In this manner, an amount of hole injections from the front surface 21 to the back surface 23 in the diode portion 80 becomes greater than an amount of hole injections from the transistor portion 70 to the diode portion 80, and it is possible to reduce the forward voltage Vf of the diode portion 80.

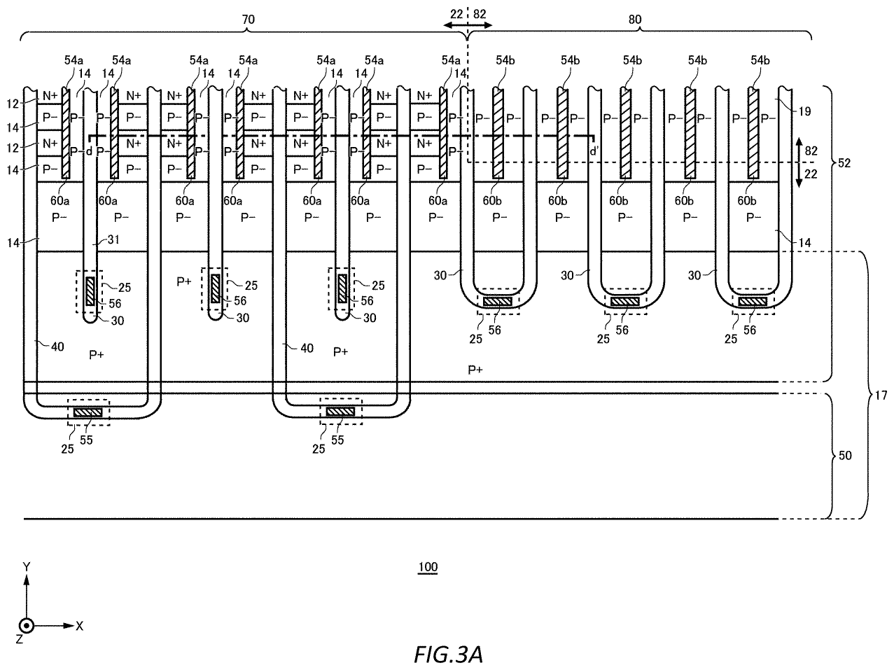

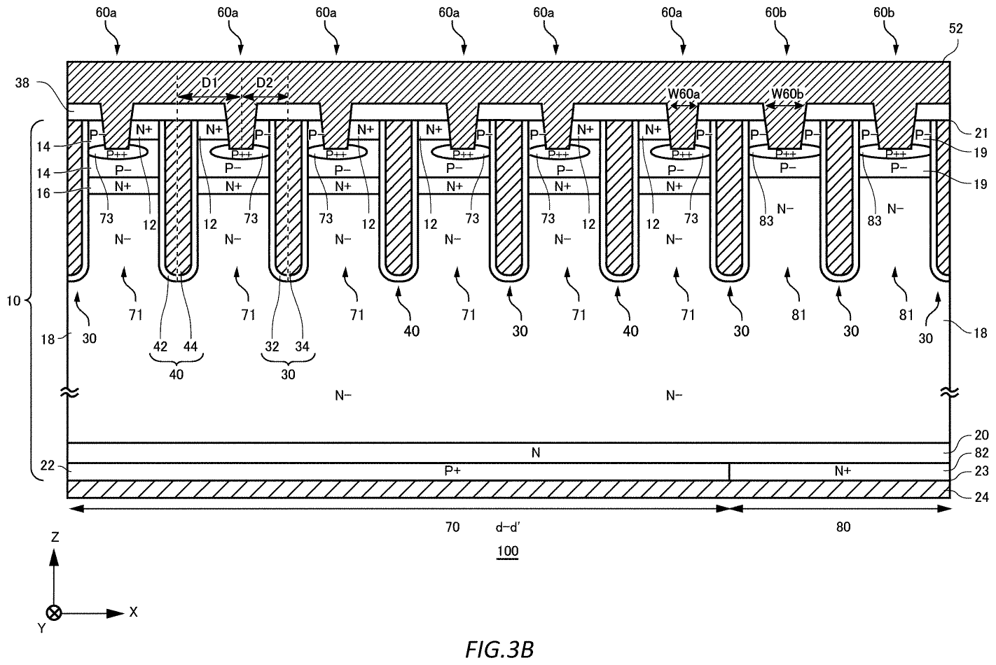

FIG. 3A is a view showing a modified example of the upper surface of the semiconductor device 100. With reference to FIG. 3A, a difference from FIG. 1A will be described.

A width of a contact hole 54a in the transistor portion 70 in the trench array direction may be the same as, or may be different from a width of a contact hole 54b in the diode portion 80 in the trench array direction. A width of a trench contact portion 60a in the transistor portion 70 in the trench array direction may be the same as, or may be different from a width of a trench contact portion 60b in the diode portion 80 in the trench array direction. In an example, in the array direction of the trench portion, the width of the trench contact portion 60b in the diode portion 80 is the same as the width of the trench contact portion 60a in the transistor portion 70. In the example of FIG. 3A, in the array direction of the trench portion, the width of the trench contact portion 60b in the diode portion 80 is greater than the width of the trench contact portion 60a in the transistor portion 70.

In the mesa portion provided between the gate trench portion 40 and the dummy trench portion 30, the trench contact portion 60 may be provided to be closer to the dummy trench portion 30 than to the gate trench portion 40. In the present example, the trench contact portion 60a in the transistor portion 70 is provided to be closer to the dummy trench portion 30 than to the gate trench portion 40.

In the transistor portion 70, the emitter region 12 may not be provided between the trench contact portion 60a and the dummy trench portion 30. In the present example, the base region 14 is provided between the trench contact portion 60a and the dummy trench portion 30.

FIG. 3B shows an example of a cross section d-d′ in FIG. 3A. The cross section d-d′ is an XZ plane which passes through the emitter region 12 in the transistor portion 70. With reference to FIG. 3B, a difference from FIG. 1B will be described.

In the array direction of the trench portion, the width of the trench contact portion 60 in the diode portion 80 may be greater than the width of the trench contact portion 60a in the transistor portion 70. The width of the trench contact portion 60 may be an opening width at an upper end of the interlayer dielectric film 38, may be a width at the bottom portion of the trench contact portion 60, or may be a width at the same depth as that of the front surface 21 of the semiconductor substrate 10. In the present example, a width W60b of the trench contact portion 60b in the diode portion 80 is greater than a width W60a of the trench contact portion 60a in the transistor portion 70. In this manner, when the first contact region 73 and the second contact region 83 are formed, it is possible to implant more dopants via the trench contact portion 60b with a wide width than via the trench contact portion 60a with a narrow width, and thus it is possible to cause the doping concentration of the second contact region 83 to be higher than that of the first contact region 73.

In the mesa portion provided between the gate trench portion 40 and the dummy trench portion 30, the trench contact portion 60a in the transistor portion 70 may be provided to be closer to the dummy trench portion 30 than to the gate trench portion 40. In the present example, in the mesa portion 71, a distance D1 between the center of the trench contact portion 60a and the gate trench portion 40 is greater than a distance D2 between the center of the trench contact portion 60a and the dummy trench portion 30. This makes it possible to arrange the first contact region 73 to be spaced apart from the gate trench portion 40, and it is possible to reduce a variation in threshold value that occurs by a low concentration part of the first contact region 73, which is formed by the first contact region 73 being diffused in the trench array direction (the X axis direction), coming into contact with a side wall of the gate trench portion 40.

In the diode portion 80, the second contact region 83 may be provided to be in contact with the dummy trench portion 30. In the present example, in the mesa portion 81 sandwiched between two dummy trench portions 30 of the diode portion 80, the second contact region 83 is provided to extend from a side wall of one dummy trench portion 30 to a side wall of another dummy trench portion 30. This makes it possible to cause the amount per unit volume of dopants of the second conductivity type in the diode portion 80 to be greater than the amount per unit volume of dopants of the second conductivity type in the transistor portion 70.

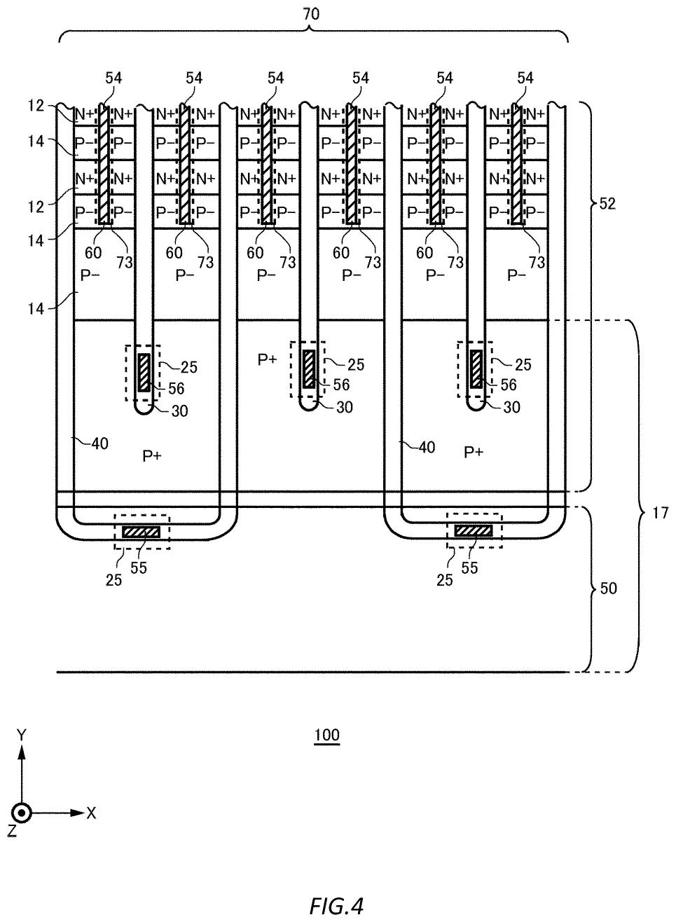

FIG. 4 is a view showing a modified example of the upper surface of the semiconductor device 100. The semiconductor device 100 has the transistor portion. The semiconductor device 100 includes the drift region 18, the base region 14, the emitter region 12, the first contact region 73, and the trench contact portion 60. The configuration of each of these regions may be the same as the configuration of the semiconductor device 100 described above, and therefore will be omitted.

In the semiconductor device 100 shown in FIG. 4, the first contact region 73 is not provided at the front surface 21. At the front surface 21 of the semiconductor device 100, the emitter regions 12 and base regions 14 are provided alternately in the trench extension direction.

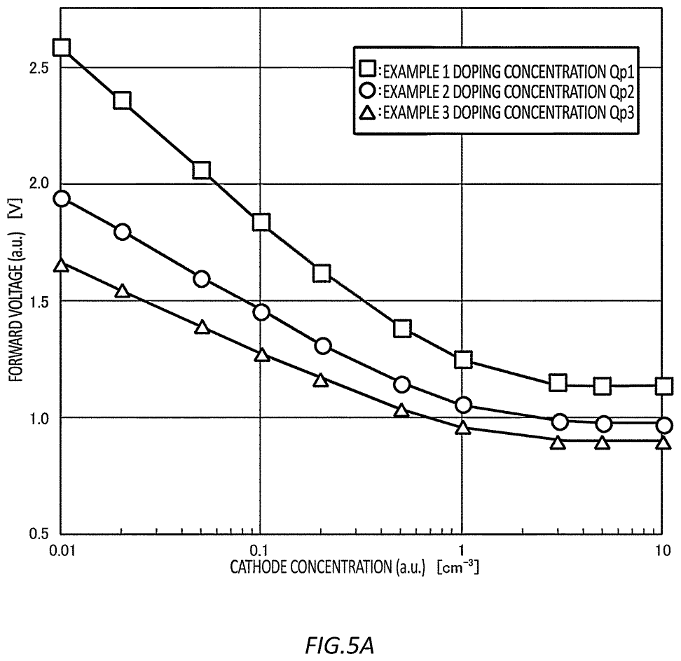

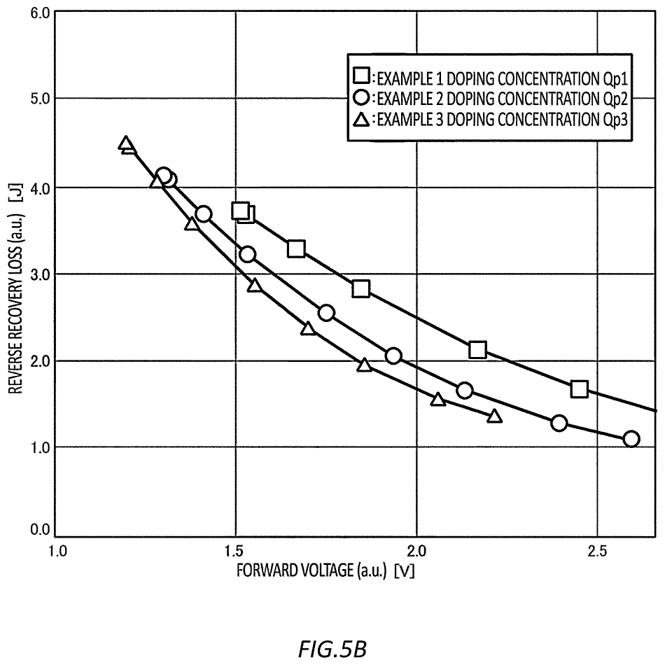

FIG. 5A is a diagram showing a relationship between a doping concentration of the cathode region 82 and the forward voltage Vf of the diode portion 80. The horizontal axis represents the doping concentration of the cathode region 82, and the vertical axis represents the forward voltage Vf of the diode portion 80; and the amount per unit volume of dopants of the second conductivity type in the mesa portion 81 of the diode portion 80 is changed for plotting. Each value is normalized.

In example 1 to example 3, the amounts per unit volume of dopants of the second conductivity type in the mesa portion 81 of the diode portion 80 are different from each other. A doping concentration Qp1 of the second conductivity type dopant in example 1, which is indicated by a square, is lower than a doping concentration Qp2 in example 2, which is indicated by a circle. The doping concentration Qp2 in example 2 is lower than a doping concentration Qp3 in example 3, which is indicated by a triangle. When the amount per unit volume of dopants of the second conductivity type in the mesa portion 81 of the diode portion 80, is increased, the forward voltage Vf of the diode portion 80 is decreased.

When the doping concentration of the cathode region 82 is decreased, the forward voltage Vf of the diode portion 80 is increased. As an example, by providing the second cathode portion 182 in the cathode region 82, it is possible to increase the forward voltage Vf of the diode portion 80. In this manner, by adjusting the amount per unit volume of dopants of the second conductivity type in the mesa portion 81 of the diode portion 80, and the doping concentration of the cathode region 82, it is possible to adjust the value of the forward voltage Vf of the diode portion 80.

FIG. 5B is a diagram showing a relationship between the forward voltage Vf and the reverse recovery loss Err of the diode portion 80. The horizontal axis represents the forward voltage Vf of the diode portion 80, and the vertical axis represents the reverse recovery loss Err; and the amount per unit volume of dopants of the second conductivity type in the mesa portion 81 of the diode portion 80 is changed for plotting. Each value is normalized.

The relationship between the amounts per unit volume of dopants of the second conductivity type in the mesa portion 81 of the diode portion 80 in respective example 1, example 2, and example 3 is as described above. When the amount per unit volume of dopants of the second conductivity type in the mesa portion 81 of the diode portion 80, is increased, the forward voltage Vf of the diode portion 80 is decreased, and the reverse recovery loss Err is increased. In this manner, by adjusting the amount per unit volume of dopants of the second conductivity type in the mesa portion 81 of the diode portion 80, and the doping concentration of the cathode region 82, it is possible to adjust a relationship between the forward voltage Vf and the reverse recovery loss Err.

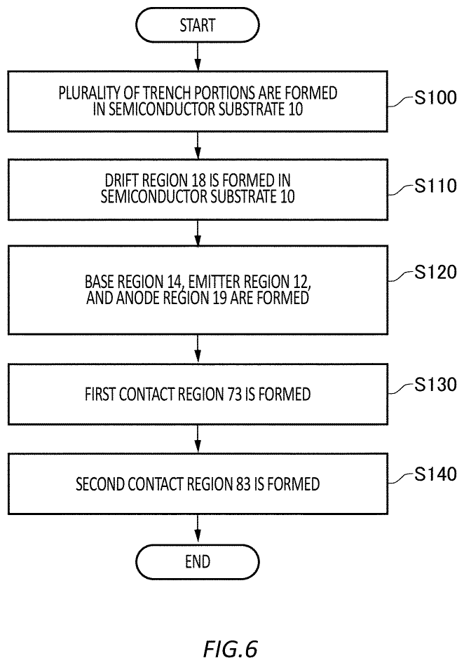

FIG. 6 is a flowchart showing an example of a method for manufacturing the semiconductor device 100. The method for manufacturing the semiconductor device 100 in the present example includes: step S100 of forming the plurality of trench portions in the semiconductor substrate 10; step S110 of forming the drift region 18 in the semiconductor substrate 10; step S120 of forming the base region 14, the emitter region 12, and the anode region 19; a first ion implantation step S130 of forming the first contact region 73; and a second ion implantation step S140 of forming the second contact region 83. Among these, regarding step S100 of forming the plurality of trench portions in the semiconductor substrate 10; step S110 of forming the drift region 18 in the semiconductor substrate 10; and step S120 of forming the base region 14, the emitter region 12, and the anode region 19, it is possible for anyone with ordinary knowledge to understand the contents, and thus descriptions thereof will be omitted.

A dose of ions which are implanted in the first ion implantation step S130 may be different from a dose of ions which are implanted in the second ion implantation step S140. The first ion implantation step S130 and the second ion implantation step S140 may be performed by using masks different from each other, at timings different from each other. In the present example, a dose of dopants of the second conductivity type which are implanted in the second ion implantation step S140 is greater than a dose of dopants of the second conductivity type which are implanted in the first ion implantation step S130. This makes it possible to cause the amount per unit volume of dopants of the second conductivity type in the diode portion 80 to be greater than the amount per unit volume of dopants of the second conductivity type in the transistor portion 70.

The first ion implantation step S130 may be the same ion implantation step as the second ion implantation step S140. The first ion implantation step S130 and the second ion implantation step S140 may be performed by using the same mask, at the same timing. The first contact region 73 and the second contact region 83 may be formed by using the same mask, at the same timing, or may be formed at timings different from each other.

While the present invention has been described above with the embodiments, the technical scope of the present invention is not limited to the above-described embodiments. It is apparent to persons skilled in the art that various alterations or improvements can be made to the above-described embodiments. It is also apparent from the described scope of the claims that the embodiments to which such alterations or improvements are made can be included in the technical scope of the present invention.

It should be noted that the operations, procedures, steps, stages, or the like of each process performed by a device, system, program, and method shown in the claims, the specification, or the drawings can be performed in any order as long as the order is not indicated by “prior to,” “before,” or the like and as long as the output from a previous process is not used in a later process. Even if the process flow is described using phrases such as “first” or “next” in the claims, the specification, or the drawings for the sake of convenience, it does not necessarily mean that the process must be performed in this order. (Item 1)

A semiconductor device which includes a transistor portion and a diode portion, the semiconductor device including:
a plurality of trench portions which are provided at a front surface of a semiconductor substrate;
a drift region of a first conductivity type which is provided in the semiconductor substrate;
a base region of a second conductivity type which is provided above the drift region;
an emitter region of the first conductivity type which is provided above the base region and which has a doping concentration higher than that of the drift region;
a first contact region of the second conductivity type which is provided in a mesa portion of the transistor portion and which has a doping concentration higher than that of the base region;
an anode region of the second conductivity type which is provided above the drift region, in the diode portion; and
a second contact region of the second conductivity type which is provided in a mesa portion of the diode portion and which has a doping concentration higher than that of the anode region, in which
an amount per unit volume of dopants of the second conductivity type in the mesa portion of the diode portion is greater than or equal to an amount per unit volume of dopants of the second conductivity type in the mesa portion of the transistor portion.

### (Item 2)

The semiconductor device according to item 1, including a trench contact portion in each of the transistor portion and the diode portion.

### (Item 3)

The semiconductor device according to item 2, in which a depth of a lower end of the trench contact portion is deeper than a depth of a lower end of the emitter region, in a depth direction of the semiconductor substrate.

### (Item 4)

The semiconductor device according to item 2, in which the first contact region is provided at a lower end of the trench contact portion.

### (Item 5)

The semiconductor device according to item 2, in which the second contact region is provided at a lower end of the trench contact portion.

### (Item 6)

The semiconductor device according to item 2, in which in an array direction of the plurality of trench portions, a width of the trench contact portion in the diode portion is the same as a width of the trench contact portion in the transistor portion.

### (Item 7)

The semiconductor device according to item 2, in which in an array direction of the plurality of trench portions, a width of the trench contact portion in the diode portion is greater than a width of the trench contact portion in the transistor portion.

### (Item 8)

The semiconductor device according to item 2, in which the plurality of trench portions have a gate trench portion to which a gate potential is applied, and a dummy trench portion to which a potential different from the gate potential is applied, and
in a mesa portion provided between the gate trench portion and the dummy trench portion, the trench contact portion is provided to be closer to the dummy trench portion than to the gate trench portion.

### (Item 9)

The semiconductor device according to item 1, in which a doping concentration of the first contact region in the transistor portion is 1E19 cm⁻³ or more, and 1E21 cm⁻³ or less.

### (Item 10)

The semiconductor device according to item 1, in which in the transistor portion, the first contact region is provided to extend in an extension direction of the plurality of trench portions.

### (Item 11)

The semiconductor device according to item 1, in which in the transistor portion, the first contact region is provided to be spaced apart from the emitter region.

### (Item 12)

The semiconductor device according to item 1, in which the plurality of trench portions have a gate trench portion to which a gate potential is applied, and a dummy trench portion to which a potential different from the gate potential is applied, and
in the transistor portion, the first contact region is provided to be spaced apart from the gate trench portion.

### (Item 13)

The semiconductor device according to item 1, in which a doping concentration of the second contact region in the diode portion is 1E19 cm⁻³ or more, and 1E21 cm⁻³ or less.

### (Item 14)

The semiconductor device according to item 1, in which in the diode portion, the second contact region is provided to extend in an extension direction of the plurality of trench portions.

### (Item 15)

The semiconductor device according to item 1, in which the plurality of trench portions have a gate trench portion to which a gate potential is applied, and a dummy trench portion to which a potential different from the gate potential is applied, and
in a mesa portion sandwiched between two dummy trench portions, each of which is the dummy trench portion, of the diode portion, the second contact region is provided to extend from a side wall of one of the two dummy trench portions to a side wall of another of the two dummy trench portions.

### (Item 16)

The semiconductor device according to item 1, in which at the front surface of the semiconductor substrate, the emitter region and the base region are alternately provided in an extension direction of the plurality of trench portions.

### (Item 17)

The semiconductor device according to item 1, in which at the front surface of the semiconductor substrate, the emitter region is provided to extend in an extension direction of the plurality of trench portions.

### (Item 18)

The semiconductor device according to item 1, in which a doping concentration of the base region is the same as a doping concentration of the anode region.

### (Item 19)

The semiconductor device according to item 1, including a cathode region of the first conductivity type which is provided on a back surface of the semiconductor substrate and which has a doping concentration higher than that of the drift region, in which
the doping concentration of the cathode region is 1E18 cm⁻³ or more, and 1E21 cm⁻³ or less.

### (Item 20)

The semiconductor device according to item 1, including an accumulation region of the first conductivity type which has a doping concentration higher than that of the drift region, in the transistor portion.

### (Item 21)

The semiconductor device according to any one of items 1 to 20, in which the semiconductor substrate does not have a lifetime control region.

### (Item 22)

The semiconductor device according to any one of items 1 to 20, in which the transistor portion has a main region which is operated as a transistor, and the main region of the transistor portion is provided to be adjacent to the diode portion.

### (Item 23)

The semiconductor device according to item 22, in which the amount per unit volume of dopants of the second conductivity type in the mesa portion of the diode portion is greater than or equal to an amount per unit volume of dopants of the second conductivity type in a mesa portion of the main region.

### (Item 24)

A semiconductor device which has a transistor portion, the semiconductor device including:
a drift region of a first conductivity type which is provided in a semiconductor substrate;
a base region of a second conductivity type which is provided above the drift region;
a first contact region of the second conductivity type which is provided in a mesa portion of the transistor portion and which has a doping concentration higher than that of the base region; and
a trench contact portion which is provided at a front surface of the semiconductor substrate, in which
the first contact region is not provided at the front surface of the semiconductor substrate.

### (Item 25)

A method for manufacturing a semiconductor device which includes a transistor portion and a diode portion, the method including:
providing a plurality of trench portions at a front surface of a semiconductor substrate;
providing a drift region of a first conductivity type in the semiconductor substrate;
providing a base region of a second conductivity type above the drift region;
providing an emitter region of the first conductivity type which has a doping concentration higher than that of the drift region, above the base region;
providing an anode region of the second conductivity type in the diode portion, above the drift region;
performing a first ion implantation to provide a first contact region of the second conductivity type which has a doping concentration higher than that of the base region, in a mesa portion of the transistor portion; and
performing a second ion implantation to provide a second contact region of the second conductivity type which has a doping concentration higher than that of the anode region, above the drift region in the diode portion, in which
an amount per unit volume of dopants of the second conductivity type in the mesa portion of the diode portion is greater than or equal to an amount per unit volume of dopants of the second conductivity type in the mesa portion of the transistor portion.

### (Item 26)

The method for manufacturing a semiconductor device according to item 25, in which the performing the first ion implantation is performing the ion implantation which is the same as the second ion implantation.

### (Item 27)

The method for manufacturing a semiconductor device according to item 25, in which a dose of ions which are implanted in performing the first ion implantation is different from a dose of ions which are implanted in performing the second ion implantation.

### (Item 28)

The semiconductor device according to item 1, in which a doping concentration of the second contact region is higher than a doping concentration of the first contact region. (Item 29)

The method for manufacturing a semiconductor device according to item 25, in which a doping concentration of the second contact region is higher than a doping concentration of the first contact region. (Item 30)

The semiconductor device according to item 24, including: a plurality of trench portions which are provided at the front surface of the semiconductor substrate; and
an emitter region of the first conductivity type which is provided above the base region and which has a doping concentration higher than that of the drift region, in which
at the front surface of the semiconductor substrate, the emitter region and the base region are alternately provided in an extension direction of the plurality of trench portions.

### (Item 31)

The semiconductor device according to item 24, including a plurality of trench portions which are provided at the front surface of the semiconductor substrate; and
an emitter region of the first conductivity type which is provided above the base region and which has a doping concentration higher than that of the drift region, in which
the emitter region extends in a trench extension direction of the plurality of trench portions, and which is provided to cover an end portion of the trench contact portion in the trench extension direction in a top plan view.

### EXPLANATION OF REFERENCES

10: semiconductor substrate; 12: emitter region; 14: base region; 16: accumulation region; 17: well region; 18: drift region; 19: anode region; 20: buffer region; 21: front surface; 22: collector region; 23: back surface; 24: collector electrode; 25: connection portion; 30: dummy trench portion; 31: extension part; 32: dummy dielectric film; 33: connection part; 34: dummy conductive portion; 38: interlayer dielectric film; 40: gate trench portion; 41: extension part; 42: gate dielectric film; 43: connection part; 44: gate conductive portion; 50: gate metal layer; 52: emitter electrode; 54: contact hole; 55: contact hole; 56: contact hole; 60: trench contact portion; 70: transistor portion; 71: mesa portion; 73: first contact region; 75: main region; 80: diode portion; 81: mesa portion; 82: cathode region; 83: second contact region; 181: first cathode portion; 182: second cathode portion; 100: semiconductor device.

What is claimed is:

1. A semiconductor device which includes a transistor portion and a diode portion, the semiconductor device comprising:
a plurality of trench portions which are provided at a front surface of a semiconductor substrate;
a drift region of a first conductivity type which is provided in the semiconductor substrate;
a base region of a second conductivity type which is provided above the drift region;
an emitter region of the first conductivity type which is provided above the base region and which has a doping concentration higher than that of the drift region;
a first contact region of the second conductivity type which is provided in a mesa portion of the transistor portion and which has a doping concentration higher than that of the base region;
an anode region of the second conductivity type which is provided above the drift region, in the diode portion; and
a second contact region of the second conductivity type which is provided in a mesa portion of the diode portion and which has a doping concentration higher than that of the anode region, wherein
an amount per unit volume of dopants of the second conductivity type in the mesa portion of the diode portion is greater than or equal to an amount per unit volume of dopants of the second conductivity type in the mesa portion of the transistor portion.

2. The semiconductor device according to claim 1, comprising:
a trench contact portion in each of the transistor portion and the diode portion.

3. The semiconductor device according to claim 2, wherein
a depth of a lower end of the trench contact portion is deeper than a depth of a lower end of the emitter region, in a depth direction of the semiconductor substrate.

4. The semiconductor device according to claim 2, wherein
the first contact region is provided at a lower end of the trench contact portion.

5. The semiconductor device according to claim 2, wherein
the second contact region is provided at a lower end of the trench contact portion.

6. The semiconductor device according to claim 2, wherein
in an array direction of the plurality of trench portions, a width of the trench contact portion in the diode portion is the same as a width of the trench contact portion in the transistor portion.

7. The semiconductor device according to claim 2, wherein
in an array direction of the plurality of trench portions, a width of the trench contact portion in the diode portion is greater than a width of the trench contact portion in the transistor portion.

8. The semiconductor device according to claim 2, wherein
the plurality of trench portions have a gate trench portion to which a gate potential is applied, and a dummy trench portion to which a potential different from the gate potential is applied, and
in a mesa portion provided between the gate trench portion and the dummy trench portion, the trench contact portion is provided to be closer to the dummy trench portion than to the gate trench portion.

9. The semiconductor device according to claim 1, wherein
a doping concentration of the first contact region in the transistor portion is 1E19 cm⁻³ or more, and 1E21 cm⁻³ or less.

10. The semiconductor device according to claim 1, wherein
in the transistor portion, the first contact region is provided to extend in an extension direction of the plurality of trench portions.

11. The semiconductor device according to claim 1, wherein
in the transistor portion, the first contact region is provided to be spaced apart from the emitter region.

12. The semiconductor device according to claim 1, wherein
the plurality of trench portions have a gate trench portion to which a gate potential is applied, and a dummy trench portion to which a potential different from the gate potential is applied, and
in the transistor portion, the first contact region is provided to be spaced apart from the gate trench portion.

13. The semiconductor device according to claim 1, wherein
a doping concentration of the second contact region in the diode portion is 1E19 cm⁻³ or more, and 1E21 cm⁻³ or less.

14. The semiconductor device according to claim 1, wherein
in the diode portion, the second contact region is provided to extend in an extension direction of the plurality of trench portions.

15. The semiconductor device according to claim 1, wherein
the plurality of trench portions have a gate trench portion to which a gate potential is applied, and a dummy trench portion to which a potential different from the gate potential is applied, and
in a mesa portion sandwiched between two dummy trench portions, each of which is the dummy trench portion, of the diode portion, the second contact region is provided to extend from a side wall of one of the two dummy trench portions to a side wall of another of the two dummy trench portions.

16. The semiconductor device according to claim 1, wherein
at the front surface of the semiconductor substrate, the emitter region and the base region are alternately provided in an extension direction of the plurality of trench portions.

17. The semiconductor device according to claim 1, wherein
at the front surface of the semiconductor substrate, the emitter region is provided to extend in an extension direction of the plurality of trench portions.

18. The semiconductor device according to claim 1, wherein
a doping concentration of the base region is the same as a doping concentration of the anode region.

19. The semiconductor device according to claim 1, comprising:
a cathode region of the first conductivity type which is provided on a back surface of the semiconductor substrate and which has a doping concentration higher than that of the drift region, wherein
the doping concentration of the cathode region is 1E18 cm⁻³ or more, and 1E21 cm⁻³ or less.

20. The semiconductor device according to claim 1, comprising:
an accumulation region of the first conductivity type which has a doping concentration higher than that of the drift region, in the transistor portion.

21. The semiconductor device according to claim 1, wherein
the semiconductor substrate does not have a lifetime control region.

22. The semiconductor device according to claim 1, wherein
the transistor portion has a main region which is operated as a transistor, and
the main region of the transistor portion is provided to be adjacent to the diode portion.

23. The semiconductor device according to claim 22, wherein
the amount per unit volume of dopants of the second conductivity type in the mesa portion of the diode portion is greater than or equal to an amount per unit volume of dopants of the second conductivity type in a mesa portion of the main region.

24. The semiconductor device according to claim 1, wherein
a doping concentration of the second contact region is higher than a doping concentration of the first contact region.

25. A semiconductor device which has a transistor portion, the semiconductor device comprising:
a drift region of a first conductivity type which is provided in a semiconductor substrate;
a base region of a second conductivity type which is provided above the drift region;
a first contact region of the second conductivity type which is provided in a mesa portion of the transistor portion and which has a doping concentration higher than that of the base region; and
a trench contact portion which is provided at a front surface of the semiconductor substrate, wherein
the first contact region is not provided at the front surface of the semiconductor substrate.

26. The semiconductor device according to claim 25, comprising:
a plurality of trench portions which are provided at the front surface of the semiconductor substrate; and
an emitter region of the first conductivity type which is provided above the base region and which has a doping concentration higher than that of the drift region, wherein
at the front surface of the semiconductor substrate, the emitter region and the base region are alternately provided in an extension direction of the plurality of trench portions.

27. The semiconductor device according to claim 25, comprising:
a plurality of trench portions which are provided at the front surface of the semiconductor substrate; and
an emitter region of the first conductivity type which is provided above the base region and which has a doping concentration higher than that of the drift region, wherein
the emitter region extends in a trench extension direction of the plurality of trench portions, and which is provided to cover an end portion of the trench contact portion in the trench extension direction in a top plan view.
